(19) United States
(12) Patent Application Publication
(10) Pub. No.: US 2010/0267194 A1
(43) Pub. Date: Oct. 21, 2010

(54) METHOD FOR APPLYING ELECTRICAL CONTACTS ON SEMICONDUCTING SUBSTRATES, SEMICONDUCTING SUBSTRATE AND USE OF THE METHOD

(75) Inventors: Mónica Alemán, Freiburg (DE); Ansgar Mette, Freiburg (DE); Stefan Glunz, Freiburg (DE); Ralf Preu, Freiburg (DE)

Correspondence Address: FAEGRE & BENSON LLP;PATENT DOCKETING - INTELLECTUAL PROPERTY, 2200 WELLS FARGO CENTER, 90 SOUTH SEVENTH STREET, MINNEAPOLIS, MN, 55402-3901, US

(73) Assignees: Fraunhofer-Gesellschaft zur Förderung der angewandten Forschung e.V., München (DE); Albert-Ludwig-Universität Freiburg, Freiburg (DE)

(21) Appl. No.: 12/439,639

(22) PCT Filed: Jun. 26, 2007
(86) PCT No.: PCT/EP2007/005658

§ 371 Date: Apr. 16, 2010

(30) Foreign Application Priority Data
Aug. 29, 2006 (DE) 10 2006 040 352.5

(51) Int. Cl. H01L 31/18

(52) U.S. Cl. 438/98; 257/E31.124

(57) ABSTRACT

An electrical contact is applied on a semiconducting substrate, such as a solar cell. A layer of metallic powder is applied on the substrate. A laser beam is the guided over the substrate for local sintering and/or melting of the metallic powder. The non-sintered or non-melted metallic powder is then removed from the substrate.

### CROSS-REFERENCE TO RELATED APPLICATIONS

This application claims priority to PCT Application Ser. No. PCT/EP2007/005658, filed Jun. 26, 2007, which claims priority to DE 10 2006 040 352.5, filed Aug. 29, 2006, both of which are herein incorporated by reference in their entirety.

### TECHNICAL FIELD

The present invention relates to a method for applying at least one electrical contact on a semiconducting substrate, in particular solar cells, by means of a laser sintering method, and to a semiconducting substrate produced in this manner.

### BACKGROUND

The electrical contacts of a solar cell serve the purpose of conducting away charge carriers produced under illumination from the solar cell. For this purpose, they must have good contact to the semiconductor/silicon, good conductivity and sufficiently high mechanical adhesion.

The contacts are generally produced industrially with metallic pastes with the help of screen printing methods. The metallic lines are printed on the front-side of the solar cell through a structured screen. In a so-called firing step, the glass frit present in the paste etches through the antireflection coating (SiO₂, SiN_{X}, SiC) of the solar cell at high temperature. As a result, the actual contact between semiconductor and metal is produced [J. Nijs, E. Demesmaeker, J. Szlufcik, J. Poortmans, L. Frisson, K. De Clercq, M. Ghannam, R. Mertens, R. Van Overstraeten, 1^{st} WCPEC, p. 1242, Hawaii, 1994]. Because of impurities in the paste and also the technological limits of the method (e.g. running of the paste after printing or the minimum possible structural width in the range of ˜60-100 μm), both the electrical properties and the aspect ratio (height to width) of the screen-printed contacts are not optimal.

DE 100 46 170 A1 describes the firing of imprinted AL paste through ARC layers by means of RTP, and alternatively the introduction of grooves in the ARC layers by means of laser ablation. Accordingly, a pure AL metal layer (11) is fired through an ARC layer (12) by means of laser pulses (10), a comparison also being made to using a paste but not for the purpose of using this paste instead of the pure AL metal layer.

Grohe et al., “Boundary conditions for the industrial production of LFC cells” in: Conference Record of the 2006 IEEE 4^{th} World Conference on Photovoltaic Energy Conversion, Waikoloa, 7-12 May 2006, ISBN 1 4244 0016 3, (Cat No. 06CH37747), 2006, pp. 1032-1035, and also Schneiderlöchner et al., “Investigations on Laser-Fired Contacts for passivated rear Solar Cells”, in: Conference Record of the 29^{th} IEEE Photovoltaic Specialists Conference 2002, New Orleans, 19-24 May 2002, ISBN 0 7803 7471 1, 2002, pp. 300-303, respectively deal with the production of solar cells, in both cases a “Laser-Fired Contact (LFC)” method being used for the production of the rear-side contact, for which purpose pure metal layers made of aluminium are applied. In addition, an AL-BSF is mentioned in Schneiderlöchner et al. as an alternative to the LFC for which purpose AL paste is imprinted.

U.S. Pat. No. 5,468,652 describes a method for the production of contacts (26, 28) having the features: imprinted AL paste and firing of this paste through a dielectric layer made of SiN or SiO without thereby clarifying the type of heat introduction.

U.S. Pat. No. 6,429,037 B1 forms doped areas for solar cells by forcing in doping agents from a layer by means of a laser, the layer also being able to be constructed from a plurality of layers, and only the uppermost of these layers being able to carry doping agents, with the lower layers being “fired through”. Subsequently, metal electrodes are applied galvanically without current at the irradiated places.

U.S. Pat. No. 4,931,323 forms copper conductors on substrates by means of copper paste imprinted on the surface and laser sintering.

### SUMMARY

The present invention relates to a method for applying at least one electrical contact on a semiconducting substrate, such as a solar cell. A layer of metallic powder is applied on the substrate. A laser beam is then guided over the substrate for local sintering and/or melting of the metallic powder. The non-sintered and/or non-melted metallic powder is then removed from the substrate.

While multiple embodiments are disclosed, still other embodiments of the present invention will become apparent to those skilled in the art from the following detailed description, which shows and describes illustrative embodiments of the invention. Accordingly, the drawings and detailed description are to be regarded as illustrative in nature and not restrictive.

### BRIEF DESCRIPTION OF THE DRAWINGS

FIG. 1 is a cross-sectional view of a solar cell with an applied powder layer, after a first step according to an embodiment of the present invention.

FIG. 2 is a cross-sectional view of a solar cell with contacts sintered on, after a second step according to an embodiment of the present invention.

FIG. 3 is a cross-sectional view of a solar cell with contacts sintered on, after a third step according to an embodiment of the present invention.

FIG. 4 is a cross-sectional view of a solar cell with contacts soldered on and also contacts galvanized on according to an embodiment of the present invention.

### DETAILED DESCRIPTION

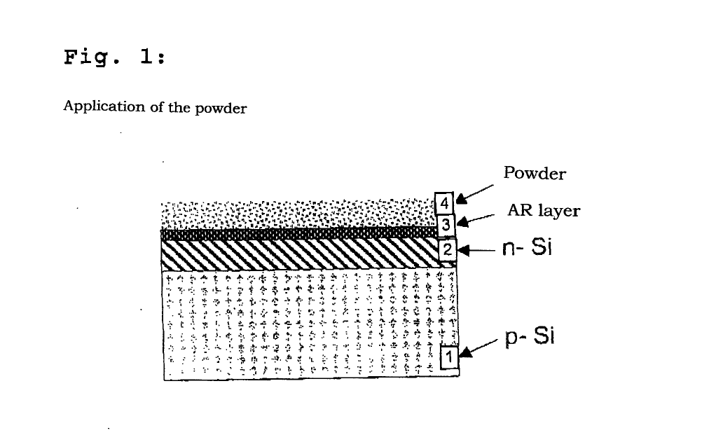

A solar cell is represented in FIG. 1, which solar cell is constructed form a positively doped silicon layer (p-layer) 1, a negatively doped silicon layer (n-layer) 2 and also an antireflection coating 3. A metallic powder 4 is applied thereon.

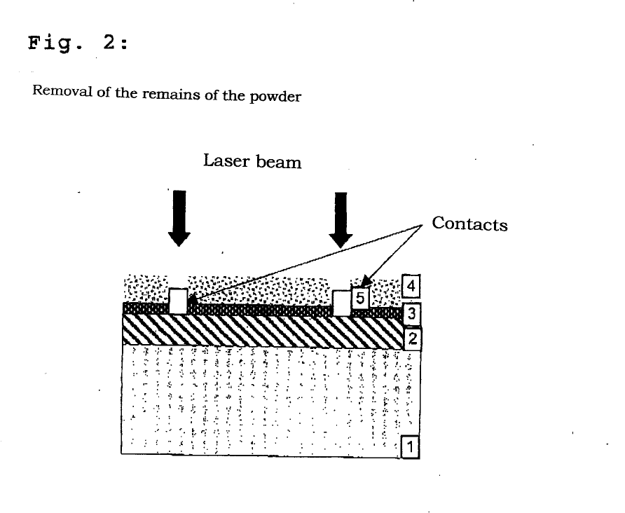

The same solar cell is represented in FIG. 2 after laser sintering and/or melting of the metallic powder 4 to form metallic contacts 5 is effected. By using laser beams, an extremely precise sintering or melting of the metallic powder is hence possible. In FIG. 2, it is likewise detectable that the laser sintering effects simultaneous perforation of the antireflection coating 3 so that, in this step, simultaneous sintering and bringing the electrical contact 5 in contact with the negatively doped layer 2 of the solar cell is possible. Hence on already continuously pre-coated substrates, extremely efficiently locally limited and arbitrarily structured conductor layers, which can be brought in contact with an electrically conductive layer of the solar cell situated thereunder, can also be applied subsequently.

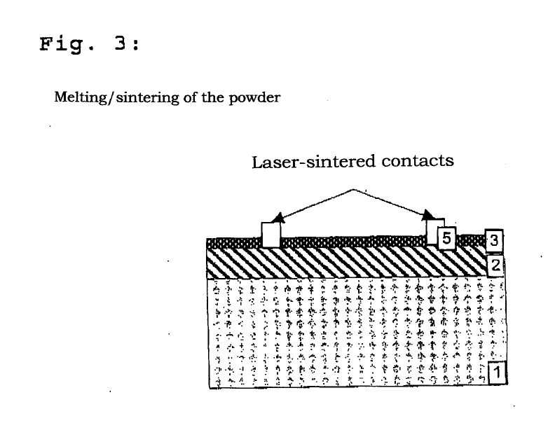

FIG. 3 shows the state of the solar cell after excess metal powder has been removed from the solar cell.

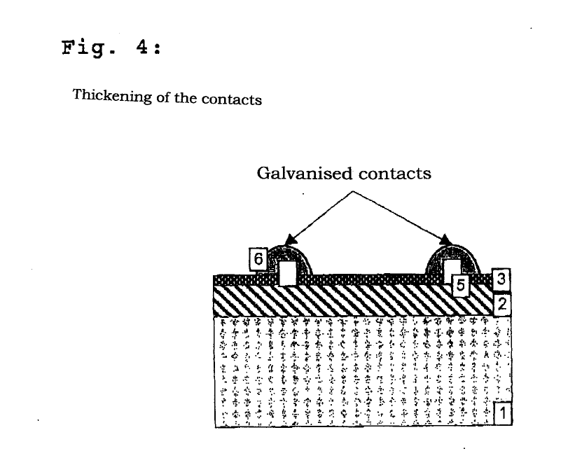

FIG. 4 shows the additional metallic contacts 6 which were applied, in this embodiment, closed over the metallic contacts 5 applied by the laser sintering method, in this case by galvanizing.

Thus, the present invention relates to a method for applying at least one electrical contact on a semiconducting substrate is provided, the following steps being implemented in succession:
a) applying a layer of a metallic powder on the substrate,
b) guiding a laser beam over the substrate for local sintering and/or melting of the metallic powder,
c) removing the non-sintered and/or non-melted metallic powder.

According to the invention there is understood by the term of a metallic powder of course both individual metals and alloys comprising several metals.

The method is particularly suitable for applying electrical contacts on solar cells.

In one embodiment, the contacts applied on the substrate have a thickness of 10 nm to 20 μm, preferably between 10 nm and 3 μm and more preferably between 80 nm and 200 nm.

In order to avoid oxidation or overheating of the metallic powder during the sintering, it is preferred that the operation takes place in an inert atmosphere or in a vacuum. It is favorable for this purpose if the inert gas is selected from the group comprising nitrogen, argon, N₂H₂ (forming gas) and/or mixtures thereof.

In another embodiment, the substrate to be coated is already coated before applying an electrical contact. In particular in the case of solar cells, this can be for example insulating layers or antireflection coatings.

Of course, it is thereby also possible that the coating of the substrate itself is constructed from the sequence of a plurality of layers, so-called layer sequences. The materials of the coating and/or of the individual layer sequences of the coating may be selected from the group of materials comprising silicon dioxide, silicon nitride, silicon carbide and/or mixtures thereof.

One advantage of the method according to the invention is that, when using already coated substrates, the possibility is offered that, in method step b), the coating is perforated during the sintering and/or melting of the metallic powder and hence the electrical contact can be applied on the semiconducting substrate. Hence in one method step (step b)), the production of a closed electrical contact and simultaneously the perforation of an insulating or antireflection coating is provided.

The metallic powder may contain at least one metal which is selected from the group comprising nickel, tungsten, chromium, molybdenum, magnesium, silver, cobalt, cadmium, titanium, palladium and/or mixtures thereof.

The particle size of the metallic powder is, in some embodiments, from 1 nm to 100 μm, preferably between 100 nm and 10 μm, and more preferably between 500 nm and 2 μm.

In a further embodiment, the metallic powder layer is applied, in step a), at a thickness of 1 μm and 1 mm, preferably between 200 μm and 800 μm, and more preferably between 500 μm and 800 μm.

Furthermore, at least one supplement may be added to the metal powder to assist the alloying process. The supplements cause dissolving of the coating and/or an improvement in the adhesion of the metallic contact.

The supplements may be selected from the group comprising glass frits, such as e.g. lead borosilicate or glass; organic compounds, doping agents for n- or p-type-doped regions, such as e.g. phosphorus- or boron powders and/or mixtures thereof.

The laser used is not limited, as long as sintering and/or melting of the metal powder by the laser radiation is ensured. The laser can in general emit in the infrared, visible and/or ultraviolet range of the electromagnetic spectrum.

In some embodiments, a solid laser is used, in particular an Nd:YAG laser. The laser used can be operated both pulsed and continuously.

The laser can thereby be operated with a power in the range of 1 W to 60 W, preferably 1 W to 20 W, and more preferably 2 W to 6 W.

In some embodiments, the laser beam is guided over the substrate at a rate of 10 mm/s to 10 m/s, preferably 100 mm/s to 2 m/s, and more preferably 200 mm/s to 600 mm/s.

The laser energy is chosen and combined with the rate of the laser beam over the substrate such that, on the one hand, the powder is sufficiently sintered so that sufficient contact is produced and, on the other hand, no significant damage to the solar cell structure situated thereunder occurs.

Another advantage of the method is that the non-sintered material can be collected again in step c), for example by suctioning off, gathering in, rinsing off or shaking off. Hence the method provides high material efficiency and also the possibility of recycling of any materials not used. This is regarded as advantageous both from an ecological and economic aspect.

In order to achieve better conductivity, it is advantageous if, subsequent to method step c), a reinforcement of the electrical contacts is effected by further application of metal. In some embodiments, the application is effected by a galvanic method. The galvanically applied metal may be selected from the group comprising copper, silver and/or mixtures thereof.

In this way, the possibility arises of applying electrical contacts on a semiconducting substrate, which contacts have a good electrical contact to the respective semiconducting element, for example silicon, but do not have such high conductivity. Hence it is possible in addition to optimize the electrical contacts sintered by means of the laser with respect to contact resistance and adhesive strength whilst the layer galvanized thereon ensures high conductivity. In some embodiments, the galvanized contacts are sintered subsequently at temperatures of for example 250° C. to 400° C. in order to lower the contact resistance further.

Furthermore, after production of the electrical contacts is concluded, which also possibly includes galvanic application of further metals on the contacts, the semiconducting substrate may be covered with a coating. In some embodiments, the coating is an antireflection coating. The coating may be constructed in turn from individual layer sequences. In some embodiments, materials selected from the group comprising silicon dioxide, silicon nitride, silicon carbide and/or mixtures thereof.

According to embodiments of the invention, a substrate is provided, which can be produced according to the method according to the invention as described in the preceding. For example, the substrate can be a solar cell.

The method for applying at least one electrical contact on a substrate can likewise be applied according to the invention.

While the invention has been described with reference to an example embodiment, it will be understood by those skilled in the art that a variety of modifications, additions and deletions are within the scope of the invention, as defined by the following claims.

1-34. (canceled)

35. A method for applying at least one electrical contact on a semiconducting substrate, the method comprising:
applying a layer of a metallic powder on the substrate;
guiding a laser beam over the substrate for local sintering and/or melting of the metallic powder; and
removing the non-sintered and/or non-melted metallic powder.

36. The method of claim 35, wherein the substrate is a solar cell.

37. The method of claim 35, wherein the applied contact has a thickness of between about 80 nm and about 200 nm.

38. The method of claim 35, wherein at least the guiding step is implemented in an inert atmosphere or in a vacuum.

39. The method of claim 38, wherein the inert atmosphere includes gases selected from the group consisting of nitrogen, argon, N₂H₂, and mixtures thereof.

40. The method of claim 35, wherein the substrate is coated with a coating prior to the applying step.

41. The method of claim 40, wherein the coating is an antireflection coating.

42. The method of claim 40, wherein the coating comprises a plurality of layers.

43. The method of claim 40, wherein the coating is selected from the group consisting of silicon dioxide, silicon nitride, silicon carbide and/or mixtures thereof.

44. The method of claim 40, wherein, in the guiding step, the coating is perforated during the sintering and/or melting of the metallic powder such that the electrical contact is applied on the semiconducting substrate.

45. The method of claim 35, wherein the metallic powder contains a metal, selected from the group comprising nickel, tungsten, chromium, molybdenum, magnesium, silver, cobalt, cadmium, titanium, palladium and/or mixtures thereof.

46. The method of claim 35, wherein a diameter of the particles of the powder is between about 500 nm and about 2 μm.

47. The method of claim 35, wherein a thickness of the powder layer in the applying step is between about 500 μm to about 800 μm.

48. The method of claim 35, wherein at least one supplement is added to the metal powder.

49. The method of claim 48, wherein the supplement is selected from the group consisting of glass fits, organic compounds; doping agents for n- or p-type-doped regions and/or mixtures thereof.

50. The method of claim 35, wherein the laser emits in the infrared, visible and/or ultraviolet range of the electromagnetic spectrum.

51. The method of claim 35, wherein the laser is a solid laser.

52. The method of claim 51, wherein the solid laser is an Nd:YAG laser.

53. The method of claim 35, wherein the laser is operated with a power in a range of between about 2 W and about 6 W.

54. The method of claim 35, wherein the laser beam is guided over the substrate at a rate of between about 200 mm/s and about 600 mm/s.

55. The method of claim 35, wherein a power of the laser and/or the rate of the laser beam are selected such that damage to the substrate is avoided during sintering and/or melting.

56. The method of claim 35, wherein removal of the powder is effected by suctioning off, gathering in, rinsing off and/or shaking off.

57. The method of claim 35, and further comprising:
applying a metal to the electrical contacts for reinforcement of the electrical contacts.

58. The method of claim 57, wherein the metal is applied galvanically.

59. The method of claim 57, wherein the metal is selected from the group consisting of copper, silver and/or mixtures thereof.

60. The method of claim 57, wherein the metal is sintered after application.

61. The method of claim 60, wherein the metal is sintered at temperatures of about 250° C. to about 400° C.

62. The method of claim 35, and further comprising:
coating the substrate with a coating.

63. The method of claim 62, wherein the coating is an antireflection coating.

64. The method of claim 62, wherein the coating comprises a plurality of layers.

65. The method of claim 62, wherein the coating is selected from the group consisting of silicon dioxide, silicon nitride, silicon carbide and/or mixtures thereof.

66. A semiconducting substrate, having at least one electrical contact, produced according to the method of claim 35.

67. The substrate of claim 66, wherein the substrate is a solar cell.
